(19) United States
(12) Patent Application Publication
(10) Pub. No.: US 2025/0034344 A1
(43) Pub. Date: Jan. 30, 2025

(54) Resin Fiber Sheet, Prepreg and Method for Producing Prepreg

(71) Applicant: ASAHI KASEI KABUSHIKI KAISHA, Tokyo (JP)

(72) Inventors: Shinichiro Tachibana, Tokyo (JP); Yusaku Wakae, Tokyo (JP)

(73) Assignee: ASAHI KASEI KABUSHIKI KAISHA, Tokyo (JP)

(21) Appl. No.: 18/714,807

(22) PCT Filed: Nov. 30, 2022
(86) PCT No.: PCT/JP2022/044231

§ 371 Date: May 30, 2024

(30) Foreign Application Priority Data
Dec. 1, 2021 (JP) 2021-195635
Sep. 29, 2022 (JP) 2022-156962

(51) Int. Cl. C08J 5/24; C08K 7/18; D01F 6/56; D01F 6/94; D04H 1/4282; D04H 1/435; D04H 1/4366; H01L 23/14

(52) U.S. Cl. CPC C08J 5/246; C08J 5/249; C08K 7/18; D01F 6/56; D01F 6/94; D04H 1/4282; D04H 1/435; D04H 1/4366; C08J 2351/08; C08K 2201/003; D10B 2321/121; D10B 2331/04; D10B 2331/14; D10B 2401/063; H01L 23/145

(57) ABSTRACT

Provided are: a resin fiber sheet and a prepreg which use a laminated sheet as a raw material and which achieve excellent heat resistance, dielectric constant, dielectric loss tangent and dimensional stability (little warping); and a method for producing a prepreg using the resin fiber sheet. In one embodiment of the present invention, provided is a resin fiber sheet constituted from a poly(phenylene ether) composition fiber. The poly(phenylene ether) composition fiber contains more than 0 mass % and not more than 95 mass % of a poly(phenylene ether) and a total of not less than 5 mass % and less than 100 mass % of a liquid crystal polyester and/or a syndiotactic polystyrene, and has a single fiber diameter of 1-50 μm.

### FIELD

The present invention relates to a resin fiber sheet, a prepreg, and a method of producing a prepreg production method.

### BACKGROUND

In recent years, with the remarkable progress in information network technology and the expansion of services utilizing information networks, electronic devices are required to handle a larger amount of information and have faster processing speeds. In order to meet these demands, printed wiring boards installed in electronic devices are required to have low dielectric constants and low dielectric loss tangents, in addition to conventional properties such as insulation reliability, heat resistance, rigidity, and flame retardancy. Thus, further improvements in dielectric constant and dielectric loss tangent are being considered for resin compositions (hereinafter also referred to as matrix resin compositions) and glass cloth substrates, which are the primary insulating materials constituting printed wiring boards.

As the matrix resin composition, a mixture of polyphenylene ether (hereinafter also referred to as PPE), which has a low dielectric constant and dielectric loss tangent, and a high heat resistance, is suitably used as the material for the above-mentioned printed wiring board. For example, Patent Literature 1 describes that when a resin composition contains a specific modified polyphenylene ether, a specific cyanurate compound as a cross-linking agent, a copolymer of butadiene and styrene, and an organic peroxide in a predetermined ratio, a matrix resin composition having excellent low dielectric constant and low dielectric loss tangent can be obtained.

As a glass cloth base material, there is preferably used a low dielectric constant glass cloth of NE glass or L glass different in composition from general E glass. Conventionally, in order to reduce the dielectric constant, it is necessary to increase the amount of SiO₂ and B₂O₃ in the glass composition. To date, in low dielectric constant glass compositions actually applied to glass cloths for printed wiring boards, the SiO₂ content has often been adjusted to 45% to 60% and the B₂O₃ content has often been adjusted to 15% to 30% (Patent Literature 2 and 3). Studies have been made regarding the use of organic fibers as low dielectric constant base materials other than glass cloths (Patent Literature 4 and 5).

### CITATION LIST

### Patent Literature

[PTL 1] Japanese Unexamined Patent Publication (Kokai) No. 2017-82200
[PTL 2] Japanese Unexamined Patent Publication (Kokai) No. 63-2831
[PTL 3] Japanese Unexamined Patent Publication (Kokai) No. 11-292567
[PTL 4] Japanese Unexamined PCT Publication (Kohyo) No. 2017-502179
[PTL 5] Japanese Unexamined Patent Publication (Kokai) No. 2008-069478

### SUMMARY

### Technical Problem

However, in future high-speed transmission of 200 Gbps or more, the problem of signal deviation (skew) is becoming apparent. This problem is primarily caused by local variations in dielectric constant of the insulating layer of the substrate. The dielectric constant of a typical low dielectric constant matrix resin composition is approximately 2.0 to 3.0, whereas the dielectric constant of a low dielectric constant glass cloth base material is about 4.6 to 4.8, and thus, local variations within the substrate of low dielectric constant glass cloth substrates have become a major problem. According to the organic fibers described in Patent Literature 4 and 5, though the problem of signal deviation as described above can be reduced, because the fibers are organic fibers, sufficient heat resistance and dimensional stability as a base material, prepreg, or laminate cannot be obtained.

An object of the present invention is to provide a resin fiber sheet and prepreg serving as raw materials for laminates having excellent heat resistance, dielectric constant, dielectric loss tangent, and dimensional stability (low warpage), as well as a prepreg production method with this resin fiber sheet.

### Solution to Problem

The gist of the present invention is as described below.

[1]

A resin fiber sheet, composed of polyphenylene ether composition fibers, wherein
the polyphenylene ether composition fibers contain greater than 0% by mass and 95% by mass or less of polyphenylene ether, and a total of 5% by mass or more and less than 100% by mass of liquid crystalline polyester, syndiotactic polystyrene, or both, and have a single-filament diameter of 1 to 50 μm.
   [2]

The resin fiber sheet according to Item 1, wherein the polyphenylene ether composition fibers contain 5% to 40% by mass of polyphenylene ether, and a total of 60 to 95% by mass of liquid crystalline polyester, syndiotactic polystyrene, or both.

[3]

The resin fiber sheet according to Item 1 or 2, wherein a toughness of the polyphenylene ether composition fibers is 5 or more and 30 or less.

[4]

The resin fiber sheet according to any one of Items 1 to 3, wherein a thermal stress rise temperature of the polyphenylene ether composition fibers is 100° C. or higher and 190° C. or lower. [5]

The resin fiber sheet according to any one of Items 1 to 4, wherein the toughness of the polyphenylene ether composition fibers is 5 or more and 30 or less, and
the thermal stress rise temperature of the polyphenylene ether composition fibers is 100° C. or higher and 190° C. or lower.
   [6]

The resin fiber sheet according to any one of Items 1 to 5, wherein a number average molecular weight of the polyphenylene ether is 9000 to 21000.

[7]

The resin fiber sheet according to any one of Items 1 to 6, wherein the resin fiber sheet is a resin fiber cloth with warp and weft weave densities of 20 to 200 fibers/inch and an opening ratio of 1 to 30%.

[8]

The resin fiber sheet according to Item 5, wherein the resin fiber sheet is a resin fiber cloth with warp and weft weave densities of 20 to 90 fibers/inch and an opening ratio of 1 to 30%.

[9]

The resin fiber sheet according to any one of Items 1 to 6, wherein the resin fiber sheet is a non-woven fabric, and
the polyphenylene ether composition fibers are composed of single filaments having a single-filament diameter of 1 to 50 μm.
   [10]

A prepreg comprising the resin fiber sheet according to any one of Items 1 to 9 and a matrix resin composition.

[11]

The prepreg according to Item 10, wherein the matrix resin composition contains at least one thermosetting resin selected from the group consisting of an epoxy resin, cyanate ester resin, bismaleimide resin, polyphenylene ether resin, and bismaleimide triazine resin.

[12]

The prepreg according to Item 11, wherein the polyphenylene ether resin contains a low molecular weight polyphenylene ether having a number average molecular weight of 1000 to 5000.

[13]

The prepreg according to any one of Items 10 to 12, wherein the matrix resin composition further contains a silica filler.

[14]

The prepreg according to Item 13, wherein the silica filler is spherical silica having an average particle diameter of 2 μm or less.

[15]

The prepreg according to Item 13 or 14, wherein a content of the silica filler in the matrix resin composition is 10 to 50% by mass.

[16]

The prepreg according to any one of Items 10 to 15, wherein the matrix resin composition further contains a cross-linking agent.

[17]

The prepreg according to Item 16, wherein the cross-linking agent is a styrene-butadiene copolymer having a number average molecular weight of 1000 to 7000 and containing 20% by mass or more of styrene-derived structural units.

[18]

The prepreg according to Item 16 or 17, wherein a content of the cross-linking agent in the matrix resin composition is 3 to 30% by mass.

[19]

A prepreg production method, comprising
a varnish preparation step of preparing a matrix resin composition varnish containing a low molecular weight polyphenylene ether having a number average molecular weight of 1000 to 5000 and an organic solvent,
an impregnation step of impregnating the resin fiber sheet according to any one of Items 1 to 9 with the matrix resin composition varnish, and
a drying step of drying the resin fiber sheet impregnated with the matrix resin composition varnish.
   [20]

The method of producing a prepreg according to Item 19, wherein the organic solvent is substantially free of aromatic compounds.

[21]

The method of producing a prepreg according to Item 19 or 20, wherein the matrix resin composition varnish further contains a silica filler.

[22]

The method of producing a prepreg according to Item 21, wherein the silica filler is spherical silica having an average particle diameter of 2 μm or less.

[23]

The method of producing a prepreg according to any one of Items 19 to 22, wherein the matrix resin composition varnish further contains a cross-linking agent.

[24]

The method of producing a prepreg according to Item 23, wherein the cross-linking agent is a styrene-butadiene copolymer having a number average molecular weight of 1000 to 7000 and containing 20% by mass or more of styrene-derived structural units.

[25]

The method of producing a prepreg according to any one of Items 19 to 24, wherein in the impregnation step, the resin fiber sheet is impregnated with the matrix resin composition varnish by applying a tension of 200 N/m or less.

[26]

The prepreg according to any one of Items 10 to 18, which is used for forming an insulating layer of a printed wiring board.

[27]

The prepreg according to any one of Items 10 to 18, which is used for forming a build-up insulating layer of a printed wiring board.

[28]

A support-attached prepreg, comprising the prepreg according to any one of Items 10 to 18 and a support arranged on one or both sides of the prepreg.

[20]

The support-attached prepreg according to Item 28, wherein the support is a resin film or a metal foil.

[30]

A method of producing a support-attached prepreg, comprising a step of continuously delivering a support,
a first application step of continuously applying a matrix resin composition varnish on the support,
a step of delivering the resin fiber sheet according to any one of Items 1 to 9 by applying tension thereto with a non-mirrored roller in contact thereto,
a step of contacting the matrix resin composition varnish applied on the support with the surface of the resin fiber sheet to obtain a first resin fiber sheet composite, and
a first drying step of drying the first resin fiber sheet composite.
   [31]

The method of producing a support-attached prepreg according to Item 30, further comprising:
a second application step of continuously applying the matrix resin composition varnish on the first resin fiber sheet composite dried in the first drying step to obtain a second resin fiber sheet composite, and
a second drying step of drying the second resin fiber sheet composite.
   [32]

A laminated body, comprising the prepreg according to any one of Items 10 to 18.

[33]

A printed wiring board, comprising an insulating layer formed from a cured product of the prepreg according to Item 26.

[34]

A printed wiring board, comprising a build-up insulating layer formed from a cured product of the prepreg according to Item 27.

[35]

A semiconductor device, comprising the printed wiring board according to Item 33.

[36]

A semiconductor device, comprising the printed wiring board according to Item 34.

### Advantageous Effects of Invention

According to the present invention, there can be provided a resin fiber sheet and prepreg serving as a raw material for laminates having excellent heat resistance, dielectric constant, dielectric loss tangent, and dimensional stability (low warpage), as well as a prepreg production method with this resin fiber sheet.

### DESCRIPTION OF EMBODIMENTS

The mode (hereinafter referred to as “the present embodiment”) for carrying out the present invention will be described below. Since the embodiment below is one aspect of the present invention, the present invention is not limited to only the following embodiment. Thus, the following embodiment can be implemented with appropriate modifications within the scope of the gist of the present invention. Furthermore, “to” as used in the present description, unless otherwise specified, is meant to include the numerical values at both ends as upper and lower limits. In the present description, the upper limits and lower limits of numerical ranges can be arbitrarily combined.

### <Resin Fiber Sheet>

The resin fiber sheet according to the present embodiment is composed of polyphenylene ether (PPE) composition fibers.

In an aspect, the PPE composition fibers constituting the resin fiber sheet contain greater than 0) % by mass and 95% by mass or less of PPE, and a total of 5% by mass or more and less than 100% by mass of liquid crystal polyester, syndiotactic polystyrene, or both. In an aspect, the PPE composition fibers have a single-filament diameter of 1 to 50 μm. Each PPE composition fiber may be a fiber composed of a bundle of 10 to 500 single filaments having a single-filament diameter of 1 to 50 μm, or may be composed of the single filament described above.

In an aspect, the resin fiber sheet may be a woven resin fiber cloth, which is a woven fabric, and in an aspect, the resin fiber sheet may be a non-woven fabric.

In an aspect, the resin fiber cloth is a woven fabric in which the warp and weft weave densities of the PPE composition fibers are 20 to 200 fibers/inch, and the opening ratio is 1 to 30%. In an aspect, the PPE composition fibers constituting the resin fiber cloth are each a fiber composed of a bundle of 10 to 500 single filaments having a diameter of 1 to 50 μm.

In an aspect, the PPE composition fibers constituting the non-woven fabric are each a single filament having a diameter of 1 to 50 μm. The basis weight of the PPE composition fibers constituting the non-woven fabric is preferably 5 to 100 g/m². The basis weight is more preferably 50 g/m² or less, or 30 g/m² or less, or 20 g/m² or less. The basis weight is measured in accordance with ISO 9073-1.

In particular, the present inventors have focused on the fact that a resin fiber cloth in which PPE composition fibers containing a specific polyphenylene ether and a liquid crystal polyester, syndiotactic polystyrene, or both are woven in a specific aspect or a non-woven fabric composed of fibers of this PPE composition can be a raw material for laminates having excellent heat resistance, dielectric constant, dielectric loss tangent, and dimensional stability (low warpage).

Preferable examples of the PPE composition fibers in the resin fiber sheet, more specifically, both woven fabrics and non-woven fabrics, will be described below.

The PPE contained in the PPE composition fibers contains phenylene ether units as repeating structural units. The phenylene groups in the phenylene ether units may or may not have substituents.

The structural units of PPE contained in the PPE composition fibers may be the same as exemplified below regarding the low molecular weight PPE contained in the matrix resin composition according to an aspect.

The PPE may also contain other structural units other than phenylene ether units. The amount of other structural units is typically 30% or less, 25% or less, 20% or less, 15% or less, 10% or less, or 5% or less relative to the total number of unit structures. However, the amount of other structural units may exceed 30% of the total number of unit structures as long as the effects of the present invention are not impaired thereby.

Specific examples of the PPE include poly(2,6-dimethyl-1,4-phenylene ether), poly(2-methyl-6-ethyl-1,4-phenylene ether), poly(2-methyl-6-phenyl-1,4-phenylene ether), poly(2,6-dichloro-1,4-phenylene ether), and copolymers of 2,6-dimethylphenol and another phenol (for example, 2,3,6-trimethylphenol, 2-methyl-6-butylphenol), as well as PPE copolymers obtained by coupling 2,6-dimethylphenol and a biphenol or bisphenol.

The PPE contained in the PPE composition fibers preferably has a number average molecular weight of 9000 to 21000. When the number average molecular weight of PPE is 9000 or more, the heat resistance required of the substrate and the chemical resistance to solvents of the matrix resin composition varnish and to cleaning liquids for the substrate tend to be suitable. When the number average molecular weight of the PPE is 21000 or less, extrusion moldability during preparation of the PPE composition and during spinning tends to be suitable. The number average molecular weight of the PPE is more preferably 9500 or more, or 10000 or more, and more preferably 17000 or less, or 16000 or less.

Note that the number average molecular weight and weight average molecular weight of the present disclosure are determined in terms of standard polystyrene by gel permeation chromatography (hereinafter referred to as GPC) measurement from the relationship between the molecular weight and elution time of a standard polystyrene sample measured under the same conditions.

In one aspect, the PPE preferably contains or consists of a combination of a PPE component having a number average molecular weight of 9000 to 12000 and a PPE component having a number average molecular weight of 14000 to 17000. As a result, both heat resistance and moldability can be improved. In particular, by adjusting the blending amount of the PPE component having a number average molecular weight of 9000 to 12000 to 30 to 60% by mass relative to 100% by mass of the PPE, in addition to further improvement in both heat resistance and moldability, affinity between the resin fiber sheet and the matrix resin composition varnish during prepreg production is also improved, whereby the heat resistance and adhesion as a laminate are improved.

The number average molecular weight of the PPE component having a number average molecular weight of 9000 to 12000 may be more preferably 9500 or more, or 10000 or more, and may be 11500 or less, or 11000 or less.

The number average molecular weight of the PPE component having a number average molecular weight of 14000 to 17000 may be more preferably 14500 or more, or 15000 or more, and may be 16500 or less, or 16000 or less.

The PPE composition fibers contain liquid crystal polyester and/or syndiotactic polystyrene. All of these polymers, which can exhibit crystallinity due to the highly ordered structure of the polymer molecules while having excellent fluidity, can improve the heat resistance, mechanical strength, and/or solvent resistance of the PPE composition fibers, as well as contribute to the production of PPE composition fibers having suitable dimensional stability.

Liquid crystal polyester (hereinafter also referred to as LCP) is composed of repeating structural units derived from, for example, aromatic diols, aromatic dicarboxylic acids, or aromatic hydroxycarboxylic acids, and the chemical structure thereof is not particularly limited as long as the effects of the present invention are not impaired thereby. Furthermore, the liquid crystal polyester may contain structural units derived from aromatic diamines, aromatic hydroxyamines, or aromatic aminocarboxylic acids as long as the effects of the present invention are not impaired thereby.

The liquid crystal polyester preferably has a melting point of 200° C. to 400° C. When the melting point of the liquid crystal polyester is 200° C. or higher, the heat resistance and chemical resistance required of the substrate tend to be suitable. When the melting point of the liquid crystal polyester is 400° C. or lower, extrusion moldability during preparation of the PPE composition and during spinning, and orientation during spinning tend to be suitable. The melting point of the liquid crystal polyester is more preferably 200° C. to 380° C. or 210° C. to 350° C.

Syndiotactic polystyrene (hereinafter also referred to as sPS) is a styrenic polymer mainly having a syndiotactic structure. The syndiotactic structure is a three-dimensional structure in which the stereochemical structure is syndiotactic, i.e., the phenyl groups, which are side chains, are alternately located in opposite directions with respect to the main chain formed from carbon-carbon bonds, and the stereoregularity thereof is analyzed by the nuclear magnetic resonance method (¹³C-NMR method) using a carbon isotope. Tacticity as measured by the 3C-NMR method can be expressed by the proportion of a plurality of consecutive constituent units, such as dyads if there are two units, triads if there are three units, and pentads if there are five units. In a typical embodiment, the polystyrene resin having a syndiotactic structure may have a syndiotacticity of 75% or more, and preferably 85% or more, for racemic dyads, and may have a syndiotacticity of 30% or more, and preferably 50% or more, for racemic pentads.

The syndiotactic polystyrene preferably has a weight average molecular weight of 30,000 to 500,000. When the weight average molecular weight of the sPS is 30,000 or more, the heat resistance and chemical resistance required of the substrate tend to be suitable. When the weight average molecular weight of the sPS is 500,000 or less, extrusion moldability during preparation of the PPE composition and during spinning tends to be suitable. The weight average molecular weight of the sPS is more preferably 100,000 to 400,000, or 100,000 to 300,000.

In an aspect, the content of PPE in the PPE composition fibers is greater than 0) % by mass and 95% by mass or less, preferably 5 to 95% by mass. 10 to 70% by mass. 15 to 60% by mass, or 20 to 50% by mass. PPE inherently has excellent heat resistance. When the PPE content is greater than 0% by mass, and in particular, 5% by mass or more, the cured prepreg product exhibits excellent dielectric constant uniformity, signal shift tends to be suitably prevented, and in particular, in embodiments where the matrix resin contains PPE (preferably a low molecular weight PPE), adhesion between the matrix resin and the PPE composition fibers and the permeability of the matrix resin into the PPE composition fibers tend to be excellent. Conversely, when the content of PPE in the PPE composition fiber is 95% by mass or less, the melt spinnability is excellent.

From the viewpoint of spinnability, the upper limit of the content is preferably 50% by mass or 40% by mass.

In an aspect, the total content of the LCP and/or sPS in the PPE composition fibers is 5% by mass or more and less than 100% by mass, preferably 5 to 95% by mass, 10 to 90% by mass. 20 to 85% by mass, or 30 to 80% by mass.

When the PPE composition fibers contain PPE and LCP, the content of the LCP in the PPE composition fiber is preferably 2.5% by mass or more, or 5% by mass or more, and preferably 95% by mass or less, 90% by mass or less, 80% by mass or less, 70% by mass or less, 60% by mass or less, 50% by mass or less, 40% by mass or less, or 30% by mass or less. When the LCP content is 2.5% by mass or more, and in particular, 5% by mass or more, the heat resistance is excellent. When the LCP content is 95% by mass or less, spinnability is excellent, and in particular, when it is 30% by mass or less, stable spinning can be performed without yarn breakage.

Furthermore, in applications where a low dielectric loss tangent is particularly required, the LCP content is preferably zero.

In an aspect, when the PPE composition fibers contain PPE and sPS, the content of the sPS in the PPE composition fibers is 2.5% by mass or more, 5% by mass or more, 10% by mass or more, 20% by mass or more, 30% by mass or more, 40% by mass or more, 50% by mass or more, or 60% by mass or more, and is preferably 95% by mass or less, 90% by mass or less, or 85% by mass or less. When the sPS content is 2.5% by mass or more, and in particular, 5% by mass or more, the PPE fiber composition has excellent solvent resistance, dielectric constant, and dielectric loss tangent. In particular, when the sPS content is 40% by mass or more, the effect of crystallinity of the sPS is more pronounced, and the dimensional stability (low warpage) is excellent. When the sPS content is 95% by mass or less, the heat resistance is excellent.

It is preferable that the PPE composition fibers contain both LCP and sPS, and the total content thereof be 5% by mass or more and less than 100% by mass, 5 to 95% by mass, 10 to 90% by mass, 20 to 85% by mass, or 30 to 80% by mass, because properties such as dielectric constant, dielectric loss tangent, heat resistance, and mechanical strength are particularly excellent.

In an aspect, the toughness of the polyphenylene ether composition fibers is 5 or more and 30 or less. The toughness is preferably 5 or more, 7 or more, or 8 or more from the viewpoint of weavability, and preferably 30 or less, 20 or less, 17 or less, 15 or less, or 13 or less from the viewpoint of yarn spinnability. Toughness is a value measured by the method described in the Examples of the present disclosure.

In an aspect, the thermal stress rise temperature of the polyphenylene ether composition fibers is 100° C. or higher and 190° C. or lower. The thermal stress rise temperature is preferably 100° C. or higher, 120° C. or higher, or 130° C. or higher from the viewpoint of heat resistance and dimensional stability, and preferably 190° C. or lower or 180° C. or lower, 170° C. or lower, or 160° C. or lower from the viewpoint of yarn toughness. The thermal stress rise temperature is a value measured by the method described in the Examples of the present disclosure.

In a preferable aspect, the polyphenylene ether composition fibers contain 5 to 40% by mass of polyphenylene ether and a total of 60 to 95% by mass of liquid crystal polyester or syndiotactic polystyrene, or both, from the viewpoint of spinnability.

In addition to PPE, LCP, and/or sPS, the PPE composition fibers may further contain additional components such as a styrenic elastomer, a flame retardant, an antioxidant, an oil agent, and other additives, as needed.

As the styrene elastomer, at least one selected from the group consisting of styrene-butadiene block copolymers, styrene-ethylene-butadiene block copolymers, styrene-ethylene-butylene block copolymers, styrene-butadiene-butylene block copolymers, styrene-isoprene block copolymers, styrene-ethylene-propylene block copolymers, styrene-isobutylene block copolymers, hydrogenated products of styrene-butadiene block copolymers, hydrogenated products of styrene-ethylene-butadiene block copolymers, hydrogenated products of styrene-butadiene-butylene block copolymers, hydrogenated products of styrene-isoprene block copolymers, and styrene homopolymers (polystyrenes) is preferable, and a hydrogenated product of a styrene-butadiene block copolymer is more preferable.

As the flame retardant, conventionally-known flame retardants can be used. Examples thereof include inorganic flame retardants such as antimony trioxide, aluminum hydroxide, magnesium hydroxide, and zinc borate; aromatic bromine compounds such as hexabromobenzene, decabromodiphenylethane, 4,4-dibromobiphenyl, and ethylenebistetrabromophthalimide; and phosphorous-based flame retardants such as resorcinol bis-diphenyl phosphate and resorcinol bis-dixylenyl phosphate. These flame retardants may be used alone or in combination of two or more thereof.

In an aspect, the total content of the additional components in the PPE composition fibers is 0 to 20% by mass, preferably 0 to 15% by mass, 0 to 10% by mass, or 0 to 5% by mass.

The PPE composition can be prepared by melt-kneading the above raw materials using a twin-screw extruder or the like at, for example, 300° C. or higher. Furthermore, multi-filament fibers can be produced by heating this PPE composition to 280° C. or higher, passing it through a spinneret, extruding, and spinning using a general spinning method, and specifically, for example, a melt spinning method. Though the optimum value for the spinning speed varies depending on the composition of the resin, when, for example, the PPE content is 5 to 40% by mass and the sPS content is 60 to 95% by mass, the spinning speed is preferably 1000 to 4000 m/min. When the spinning speed is 1000 m/min or higher, the toughness tends to be suitable. Furthermore, when the spinning speed is 4000 m/min or less, decreases in toughness and yarn breakage tend to decrease. A more preferable range of spinning speed is 1500 to 3000 m/min. Further, it is preferable to further draw the fibers obtained by spinning from the viewpoint of improving toughness and thermal stability (improving thermal stress rise temperature). Drawing may be performed in a separate step from spinning, or may be performed by a spin-draw take-up method in which spinning and drawing are performed continuously. The elongation of the drawn yarns is preferably 15 to 40%, and more preferably 20 to 35%, from the viewpoint of quality such as fluff and yarn breakage. It is preferable to adjust the drawing ratio so as to achieve the elongation described above. The preheating temperature for drawing is preferably 90 to 120° C. At temperatures of 90° C. or higher, yarn breakage and single filament breakage are less likely to occur. Furthermore, the toughness is less likely to decrease at temperatures of 120° C. or lower. The heat setting temperature after drawing is preferably 120 to 180° C. At temperatures of 120° C. and higher, thermal stress rise temperature is unlikely to decrease, and at 180° C. and, the toughness is unlikely to decrease. A further preferable heat setting temperature is 130 to 170° C. Further, the relaxation ratio after heat setting is preferably 0.96 to 0.99. When it is 0.96 or more, the winding tension is less likely to decrease and yarn breakage tends to be less likely. Furthermore, when it is 0.99 or less, the thermal stress rise temperature tends to be unlikely to decrease. A more preferable range of the relaxation ratio is 0.965 to 0.985. The relaxation ratio is the value obtained by dividing the winding speed by the drawing speed. In an aspect, the diameter of single filaments (single filaments constituting the multi-filament in an aspect) is 1 to 50 μm, and preferably 5 to 50 μm. 5 to 30 μm. 5 to 20 μm, or 5 to 15 μm. In an aspect, the number of single filaments constituting the multi-filament is 10 to 500, and preferably 10 to 200, 10 to 100, or 10 to 50. When the single-filament diameter is 1 μm or more, the necessary tensile strength is developed in the subsequent weaving step and fiber-opening step, and fuzz (single filament breakage) is less likely to occur. When the single-filament diameter is 50 μm or less, the thickness generally required for substrate applications can be achieved, and in particular, when the single-filament diameter is 30 μm or less, a thickness of 30 to 100 μm, which is suitable for substrate applications, can be achieved. When the number of single filaments constituting the multi-filament is 10 or more, the dielectric constant of the insulating layer of the substrate can be made uniform by adjusting the subsequent weaving step and fiber-opening step. When the number of single filaments constituting the multi-filament is 500 or less, the fuzz (single filament breakage) described above is less likely to occur.

In an aspect of the resin fiber cloth, the resin fiber cloth is produced by weaving the PPE composition fibers described above so as to achieve warp and weft weave densities of 20 to 200 fibers/inch and an opening ratio of 1 to 30%. When the warp and weft weave densities are each 20 fibers/inch or more, it is possible to prevent distortion and achieve a uniform dielectric constant of the insulating layer of the substrate. When the warp and weft weave densities are each 200 fibers/inch or less, entanglement of fibers can be prevented and fuzz (single filament breakage) can be suppressed. The warp and weft weave densities are each preferably 20 fibers/inch to 150 fibers/inch, or 20 fibers/inch to 90 fibers/inch, or 30 fibers/inch to 70 fibers/inch.

When the opening ratio is 1% or more, it becomes easy for the matrix resin to penetrate the resin fiber cloth, improving resin impregnation and heat resistance, and since there are some areas where the resin fiber cloth is not present, adhesion between the insulating layer of the substrate and the metal foil (for example, copper foil) is improved. When the opening ratio is 30% or less, since the dielectric constant of the insulating layer of the substrate can be made uniform and the PPE composition fibers are appropriately dispersed, the heat resistance is improved. The opening ratio is preferably 5% to 25% or 10% to 20%. The warp and weft weave densities and opening ratio are values measured by the methods described in the Examples of the present disclosure. The weave structure is not particularly limited, and examples thereof include weave structures such as plain weave, basket weave, satin weave, and twill weave. Among these, a plain weave structure is more preferable.

The fiber surface of the resin fiber sheet described above may be surface-treated by silane coupling agent treatment, corona treatment, or plasma treatment. Among these, it is preferable that the fiber surface of the resin fiber sheet be treated with inert gas species plasma. The surface treatment described above tends to further improve the heat resistance and adhesive properties required of the substrate.

Note that regarding the resin fiber sheet of the present disclosure, for example, resin composition fibers which are amorphous and exhibit a glass transition temperature of 150° C. or higher may be used as another aspect other than the PPE composition fibers of the present embodiment. Specific examples thereof include fibers of a resin composition containing the sPS of the present disclosure and one or more selected from a polyamideimide, polyetherimide, polyethersulfone, polysulfone, or polyarylate.

### <Prepreg>

The prepreg according to the present embodiment comprises the resin fiber sheet described above and a matrix resin composition. The resin fiber sheet may be impregnated with the matrix resin composition. In the present embodiment, it is preferable that the matrix resin composition contain at least one type of thermosetting resin selected from the group consisting of epoxy resins, cyanate ester resins, bismaleimide resins, polyphenylene ether resins, and bismaleimide triazine resins (BT resins). In a preferable aspect, a polyphenylene ether resin is used as the matrix resin. In this case, the matrix resin composition preferably contains a low molecular weight PPE having a number average molecular weight of 1000 to 5000. The number average molecular weight is preferably 1000 or more, 1500 or more, or 2000 or more, and preferably 5000 or less, 4500 or less, or 4000 or less. In addition to the matrix resin, the matrix resin composition typically further contains a curing agent and an inorganic filler.

As an example, the prepreg according to the present embodiment can be produced by a method comprising a varnish preparation step of preparing a varnish of the matrix resin composition, preferably, a matrix resin composition varnish (hereinafter referred to sometimes as a matrix resin composition varnish) containing at least one thermosetting resin selected from the group consisting of epoxy resin, cyanate ester resin, bismaleimide resin, bismaleimide triazine resin (BT resin), and a low molecular weight polyphenylene ether having a number average molecular weight of 1000 to 5000, and an organic solvent,
an impregnation step of impregnating the resin fiber sheet described above with the matrix resin composition varnish, and
a drying step of drying the resin fiber sheet impregnated with the matrix resin composition varnish with a hot air dryer or the like. The thermosetting resin is preferably a low molecular weight polyphenylene ether having a number average molecular weight of 1000 to 5000.

In the impregnation step, it is preferable that with the tension applied to the resin fiber sheet be 200 N/m or less, the resin fiber sheet be impregnated with the matrix resin composition varnish. The tension described above is preferably 200 N/m or less, 150 N/m or less, or 100 N/m or less from the viewpoint of dimensional stability (warpage) of the substrate.

The proportion of matrix resin composition (as a solid content) in the prepreg of the present embodiment is preferably 30% by mass to 80% by mass, and more preferably 40% by mass to 70% by mass. When this proportion is 30% by mass or more, the prepreg tends to have better insulation reliability when used for electronic substrates. When this proportion is 80% by mass or less, mechanical properties such as flexural modulus of elasticity tend to be even better in applications such as electronic substrates.

### [Matrix Resin Composition]

The matrix resin composition according to the present embodiment preferably comprises at least one type of thermosetting resin selected from the group consisting of epoxy resins, cyanate ester resins, bismaleimide resins, polyphenylene ether resins, and bismaleimide triazine resins (BT resins). The polyphenylene ether resin preferably contains or is a low molecular weight PPE having a number average molecular weight of 1000 to 5000. In an aspect, the matrix resin composition contains (a) a low molecular weight PPE having a number average molecular weight of 1000 to 5000, (b) a cross-linking agent, and/or (c) a silica filler, and optionally (d) an organic peroxide, (e) a thermoplastic resin, and/or (f) a flame retardant. The matrix resin composition may be (g) a matrix resin composition varnish containing an organic solvent. The constituents which can constitute the matrix resin composition will be described below:

### [(a) Low Molecular Weight PPE]

Low molecular weight PPE contains phenylene ether units as repeating structural units. The phenylene group in the phenylene ether unit may or may not have a substituent. As used herein, the term “polyphenylene ether” includes dimers, trimers, oligomers, and polymers.

The PPE may also contain other structural units other than phenylene ether units. The amount of the other structural units is typically 30% or less, 25% or less, 20% or less, 15% or less, 10% or less, or 5% or less relative to the total number of structural units. However, the amount of the other structural units may exceed 30% of the total number of structural units as long as the effects of the present invention are not impaired thereby.

Specific examples of the PPE include poly(2,6-dimethyl-1,4-phenylene ether), poly(2-methyl-6-ethyl-1,4-phenylene ether), poly(2-methyl-6-phenyl-1,4-phenylene ether), poly(2,6-dichloro-1,4-phenylene ether), copolymers of 2,6-dimethylphenol and another phenol (for example, 2,3,6-trimethylphenol or 2-methyl-6-butylphenol), and PPE copolymers obtained by coupling 2,6-dimethylphenol and a biphenol or bisphenol, as well as PPEs having a linear or branched structure obtained by heating poly(2,6-dimethyl-1,4-phenylene ether) in a toluene solvent in the presence of a phenol compound such as a bisphenol or a trisphenol and an organic peroxide to cause a redistribution reaction. Further, the terminal hydroxyl groups of these PPEs may be substituted with functional groups containing a carbon-carbon double bond, and such PPEs are also included in the examples. Specific examples of functional groups having a carbon-carbon double bond include a vinyl group, allyl group, isopropenyl group, 1-butenyl group, 1-pentenyl group, p-vinylphenyl group, p-isopropenylphenyl group, m-vinylphenyl group, m-isopropenylphenyl group, o-vinylphenyl group, o-isopropenylphenyl group, p-vinylbenzyl group, p-isopropenylbenzyl group, m-vinylbenzyl group, m-isopropenylbenzyl group, o-vinylbenzyl group, o-isopropenylbenzyl group, p-vinylphenylethenyl group, p-vinylphenylpropenyl group, p-vinylphenylbutenyl group, m-vinylphenylethenyl group, m-vinylphenylpropenyl group, m-vinylphenylbutenyl group, o-vinylphenylethenyl group, o-vinylphenylpropenyl group, o-vinylphenylbutenyl group, methacrylic group, acrylic group, 2-ethyl acrylic group, and 2-hydroxymethyl acrylic group.

The number average molecular weight of the low molecular weight PPE is 1000 to 5000. By containing such a low molecular weight PPE in the matrix resin composition of the present embodiment, an increase in the viscosity of the matrix resin composition varnish can be suppressed, whereby it is possible to improve the applicability of the matrix resin composition varnish on the base material. By improving the applicability, it is also possible to improve various properties required of the matrix resin composition or cured product thereof. The number average molecular weight of the low molecular weight PPE is preferably 1000 to 3500 or 1500 to 3000.

Note that one low molecular weight PPE (i.e., a PPE having a number average molecular weight of 1000 to 5000) may be included in the matrix resin composition, or a combination of two or more PPEs having a number average molecular weight of 1000 to 5000 may be used.

### [(b) Cross-Linking Agent]

In an aspect, the matrix resin composition further contains a cross-linking agent. In the present embodiment, any cross-linking agent which has the ability to initiate or promote cross-linking reactions can be used. The number average molecular weight of the cross-linking agent is preferably 9,000 or less, 8,000 or less, 7,000 or less, 6,000 or less, or 5,000 or less. When the number average molecular weight of the cross-linking agent is 9,000 or less, an increase in the viscosity of the matrix resin composition varnish can be suppressed, and suitable resin fluidity can be obtained during heat molding. From the viewpoint of applicability to the prepreg, the number average molecular weight of the cross-linking agent is preferably 100 or more, 200 or more, 300 or more, 500 or more, or 1,000 or more. The number average molecular weight of the cross-linking agent is a value measured using GPC in terms of standard polystyrene.

From the viewpoint of cross-linking reactivity, the cross-linking agent preferably has an average of two or more carbon-carbon unsaturated double bonds in a single molecule. The cross-linking agent may be composed of one or more compounds. When the cross-linking agent is a polymer or oligomer, the carbon-carbon unsaturated double bond is typically located at the end of the molecule (i.e., at the end of the main chain or a branched chain), but the present embodiment is not limited thereto.

Specifically, the cross-linking agent is preferably a styrene-butadiene copolymer containing 20% by mass or more of styrene-derived structural units. Such a cross-linking agent, which is easily compatible with the PPE composition fibers and the PPE when the matrix resin is PPE (preferably a low molecular weight PPE), tends to improves the heat resistance and interlayer adhesion of the substrate. The cross-linking agent may be a commercially available product, such as Ricon 100, Ricon 181, Ricon 257, or Ricon 184 manufactured by Cray Valley.

Other examples of the cross-linking agent include trialkenyl isocyanurate compounds such as triallyl isocyanurate (TAIC), trialkenyl cyanurate compounds such as triallyl cyanurate (TAC), poly functional methacrylate compounds having two or more methacrylic groups in the molecule, polyfunctional acrylate compounds having two or more acrylic groups in the molecule, polyfunctional vinyl compounds having two or more vinyl groups in the molecule such as poly butadiene, vinylbenzyl compounds such as divinylbenzene having a vinylbenzyl group in the molecule, and polyfunctional maleimide compounds having two or more maleimide groups in the molecule, such as 4,4′-bismaleimide diphenylmethane. These cross-linking agents are preferably used in combination with a styrene-butadiene copolymer. Since the cross-linking agent contains at least one of the compounds described above, the cross-linking density becomes higher during the curing reaction (cross-linking reaction), whereby the heat resistance of the cured product of the matrix resin composition tends to increase.

In an aspect, the cross-linking agent is a styrene-butadiene copolymer having a number average molecular weight of 1,000 to 7,000 and containing 5% by mass or more of styrene-derived structural units. Such a styrene-butadiene copolymer is particularly preferable in terms of resin permeability and adhesion to the PPE composition fibers. The number average molecular weight of the styrene-butadiene copolymer is more preferably 1,000 to 6,000 or 1,000 to 5,000. The proportion of the styrene-derived structural units in the styrene-butadiene copolymer is preferably 5% by mass or more. 10% by mass or more, 15% by mass or more, or 20% by mass or more, and preferably 95% by mass or less, 90% by mass or less, or 85% by mass or less. In an aspect, the styrene-derived structural units can be confirmed by NMR.

In the matrix resin composition, the mass ratio of the matrix resin (the low molecular weight PPE in an aspect) to the cross-linking agent is preferably 25:75 to 95:5, and more preferably 32:68 to 85:15, from the viewpoint of balancing the low dielectric constant and low dielectric loss tangent with the cross-linking density of the crosslinked structure during curing.

The content of the cross-linking agent in the matrix resin composition is preferably 3% by mass or more, 4% by mass or more, or 5% by mass or more, and is preferably 30% by mass or less, 25% by mass or less, or 20% by mass or less.

### [(c) Silica Filler]

The matrix resin composition may contain a silica filler. The silica filler is preferably spherical silica. In terms of suitable impregnation of the matrix resin into the PPE resin composition fibers, the average particle diameter of the silica filler is preferably 2 μm or less, 1.8 μm or less, or 1.5 μm or less. In terms of suitable dispersability of the silica filler in the matrix resin and excellent dimensional stability (warpage) of the substrate, the average particle diameter of the silica filler is preferably 0.1 μm or more, 0.2 μm or more, or 0.3 μm or more. In an aspect, the average particle diameter is a value measured by dynamic light scattering (DLS).

The content of the silica filler in the matrix resin composition is preferably 10 to 50% by mass, 10 to 45% by mass or 10 to 40% by mass in terms of facilitating high dispersion and achieving excellent elastic modulus and dimensional stability (warpage) of the substrate.

The silica filler may be surface-treated with a silane coupling agent or the like.

### [(d) Organic Peroxide]

In the present embodiment, any organic peroxide which is capable of promoting the polymerization reaction of the matrix resin composition containing the matrix resin (the low molecular weight PPE in an aspect) and the cross-linking agent can be used. Examples of the organic peroxide include peroxides such as benzoyl peroxide, cumene hydroperoxide, 2,5-dimethylhexane-2,5-dihydroperoxide, 2,5-dimethyl-2,5-di(t-butylperoxy)hexine-3, di-t-butyl peroxide, t-butylcumyl peroxide, di(2-t-butylperoxyisopropyl)benzene, 2,5-dimethyl-2,5-di(t-butylperoxy)hexane, dicumyl peroxide, di-t-butylperoxyisophthalate, t-butylperoxy benzoate, 2,2-bis(t-butylperoxy)butane, 2,2-bis(t-butylperoxy)octane, 2,5-dimethyl-2,5-di(benzoylperoxy)hexane, di(trimethylsilyl)peroxide, trimethylsilyltriphenylsilyl peroxide. Note that a radical generator such as 2,3-dimethyl-2,3-diphenylbutane can also be used as a reaction initiator for matrix resin composition. Among these, from the viewpoint of enabling the provision of a cured product having excellent heat resistance and mechanical properties, and providing a low dielectric constant and a low dielectric loss tangent, 2,5-dimethyl-2,5-di(t-butylperoxy)hexyne-3, di(2-t-butylperoxyisopropyl)benzene, or 2,5-dimethyl-2,5-di(t-butylperoxy)hexane is preferable.

The one-minute half-life temperature of the organic peroxide is preferably 155° C. to 185° C., or 160° C. to 180° C., or 165° C. to 175° C. In the present description, the one-minute half-life temperature is the temperature at which it takes one minute for the organic peroxide to decompose so that the amount of active oxygen is halved. The one-minute half-life temperature is a value which is confirmed by a method of dissolving the organic peroxide in a radical-inactive solvent such as benzene so as to achieve a concentration of 0.05 mol/L to 0.1 mol/L, and thermally decomposing the organic peroxide solution under a nitrogen atmosphere.

By adjusting the one-minute half-life temperature of the organic peroxide to 155° C. or higher, when the matrix resin composition is subjected to heat and pressure molding, since the reaction with the cross-linking agent can be started after the matrix resin (the low molecular weight PPE in an aspect) is sufficiently melted, moldability tends to be excellent. Conversely, by setting the one-minute half-life temperature of the organic peroxide to 185° C. or lower, because the decomposition rate of organic peroxide is sufficient under normal heating and pressure molding conditions (for example, a maximum temperature of 200° C.), since the cross-linking reaction with the cross-linking agent can proceed efficiently and slowly, a cured product having suitable electrical properties (in particular, dielectric loss tangent) can be formed.

Examples of organic peroxides having a one-minute half-life temperature within the range of 155° C. to 185° C. include t-hexylperoxyisopropyl monocarbonate (155.0° C.) (the parenthetical represents the one-minute half-life temperature; the same applies below), t-butylperoxy-3,5,5-trimethylhexanoate (166.0° C.), t-butylperoxy laurate (159.4° C.), t-butylperoxyisopropyl monocarbonate (158.8° C.), t-butylperoxy 2-ethylhexyl monocarbonate (161.4° C.), t-hexylperoxybenzoate (160.3° C.), 2,5-dimethyl-2,5-di(benzoylperoxy)hexane (158.2° C.), t-butylperoxyacetate (159.9° C.), 2,2-di-(t-butylperoxy)butane (159.9° C.), t-butylperoxy benzoate (166.8° C.), n-butyl 4,4-di-(t-butylperoxy)valerate (172.5° C.), di(2-t-butylperoxyisopropyl)benzene (175.4° C.), dicumyl peroxide (175.2° C.), di-t-hexyl peroxide (176.7° C.), 2,5-dimethyl-2,5-di(t-butylperoxy)hexane (179.8° C.) and t-butylcumyl peroxide (173.3° C.).

From the viewpoint that the reaction rate can be increased, based on a total of 100% by mass of the matrix resin (low molecular weight PPE in an aspect) and cross-linking agent, the content of the organic peroxide is preferably 0.05% by mass or more, more preferably 0.1% by mass or more, further preferably 0.3% by mass or more, and even further preferably 0.5% by mass or more, and from the viewpoint of being able to keep the dielectric constant and dielectric loss tangent of the obtained cured product low, is preferably 3% by mass or less, more preferably 2% by mass or less, and further preferably 1% by mass or less.

### [(e) Thermoplastic Resin]

The matrix resin composition can contain a thermoplastic resin in addition to the matrix resin (low molecular weight PPE in an embodiment) and the cross-linking agent. The thermoplastic resin is preferably at least one selected from the group consisting of block copolymers of vinyl aromatic compounds and aliphatic hydrocarbon compounds having carbon-carbon unsaturated double bonds and hydrogenated products thereof (hydrogenated block copolymers obtained by hydrogenating a block copolymer of a vinyl aromatic compound and an aliphatic hydrocarbon compound having a carbon-carbon unsaturated double bond), and homopolymers of vinyl aromatic compounds. The content of the vinyl aromatic compound-derived units in the block copolymer or hydrogenated product thereof is preferably 20% by mass or more, and can be 99% by mass or less. By setting the content of the units derived from vinyl aromatic compounds in the block copolymer or hydrogenated product thereof to 20% by mass or more, the compatibility between the matrix resin (low molecular weight PPE an aspect) and the thermoplastic resin tends to be further improved, whereby the adhesion strength between the cured prepreg and the metal foil tends to be further improved.

It is sufficient that the vinyl aromatic compound have an aromatic ring and a vinyl group in the molecule, and examples thereof include styrene. It is sufficient that the aliphatic hydrocarbon compound having a carbon-carbon unsaturated double bond be any unsaturated hydrocarbon compound having a linear or branched structure in the molecule, and examples thereof include ethylene, propylene, butylene, isobutylene, butadiene, and isoprene. From the viewpoint of improved compatibility with the matrix resin (low molecular weight PPE in an aspect), the thermoplastic resin is preferably at least one selected from the group consisting of styrene-butadiene block copolymers, styrene-ethylene-butadiene block copolymers, styrene-ethylene-butylene block copolymers, styrene-butadiene-butylene block copolymers, styrene-isoprene block copolymers, hydrogenated products of styrene-ethylene-propylene block copolymers, styrene-isobutylene block copolymers, styrene-butadiene block copolymers, hydrogenated products of styrene-ethylene-butadiene block copolymers, hydrogenated products of styrene-butadiene-butylene block copolymers, hydrogenated products of styrene-isoprene block copolymers, and styrene homopolymers (polystyrene), and is more preferably one or more selected from the group consisting of a styrene-butadiene block copolymer, a hydrogenated product of a styrene-butadiene block copolymer, and polystyrene.

The hydrogenation rate in the hydrogenated product is not particularly limited, and some carbon-carbon unsaturated double bonds derived from the aliphatic hydrocarbon compound having carbon-carbon unsaturated double bonds may remain.

The weight average molecular weight of the thermoplastic resin is preferably 30,000 to 300,000, and more preferably 31,000 to 290,000. By setting the weight average molecular weight to 30,000 or more, the matrix resin composition of the present embodiment tends to have better heat resistance when cured. By setting the weight average molecular weight to 300,000 or less, the matrix resin composition of the present embodiment tends to have better resin fluidity during heat molding. The weight average molecular weight is a value determined by standard polystyrene conversion using gel permeation chromatography.

The content of the thermoplastic resin is preferably 2 parts by mass to 20 parts by mass, based on a total of 100 parts by mass of the matrix resin (low molecular weight PPE in an aspect) and the cross-linking agent. When the content is 2 parts by mass or more, the matrix resin composition of the present embodiment tends to exhibit a low dielectric constant, a low dielectric loss tangent, and suitable adhesion to metal foil when cured. By setting the content to 20 parts by mass or less, the matrix resin composition of the present embodiment tends to have better resin fluidity during heat molding.

### [(f) Flame Retardant]

The matrix resin composition preferably contains a flame retardant. From the viewpoint of improving heat resistance, the flame retardant is preferably incompatible with other components in the matrix resin composition after the matrix resin composition is cured. Preferably, the flame retardant is incompatible with the matrix resin (low molecular weight PPE in an aspect) and/or the cross-linking agent in the matrix resin composition after curing of the matrix resin composition. Examples of flame retardants include inorganic flame retardants such as antimony trioxide, aluminum hydroxide, magnesium hydroxide, and zinc borate; aromatic bromine compounds such as hexabromobenzene, decabromodiphenylethane. 4,4-dibromobiphenyl, and ethylenebistetrabromophthalimide; and phosphorous flame retardants such as resorcinol bis-diphenyl phosphate and resorcinol bis-dixylenyl phosphate. These flame retardants may be used alone or in combination of two or more thereof. Among these, the flame retardant is preferably decabromodiphenylethane from the viewpoint that the matrix resin composition has a low dielectric constant and a low dielectric loss tangent when cured.

Though the content of the flame retardant is not particularly limited, from the viewpoint of maintaining flame retardancy at the UL standard 94V-0 level, it is preferable, relative to a total of 100 parts by mass of the matrix resin (low molecular weight PPE in an aspect) and the cross-linking agent, 5 parts by mass or more, more preferably 10 parts by mass or more, and further preferably 15 parts by mass or more. Furthermore, from the viewpoint of maintaining a low dielectric constant and dielectric loss tangent of the obtained cured product, the content of the flame retardant is preferably 50 parts by mass or less, more preferably 45 parts by mass or less, and further preferably 40 parts by mass or less.

In addition to the components described above, the matrix resin composition may further contain additives such as a heat stabilizer, an antioxidant, a UV absorber, a surfactant, and a lubricant.

### [(g) Organic Solvent]

The matrix resin composition can be a matrix resin composition varnish containing an organic solvent from the viewpoint of obtaining suitable fluidity when impregnating the resin fiber sheet. In the prepreg production steps, it is preferable to impregnate the resin fiber sheet with the matrix resin composition varnish and then dry and remove the solvent using a hot air dryer or the like. The solid components in the matrix resin composition may be dissolved or dispersed in the varnish. The amount of organic solvent may be adjusted appropriately so that the fluidity of the matrix resin composition varnish is within a suitable range. For example, the amount of solvent in the matrix resin composition varnish may be 20 to 80% by mass, or 30 to 70% by mass, or 40 to 60% by mass.

As the organic solvent, methyl ethyl ketone, methyl isobutyl ketone, cyclopentanone, cyclohexanone, and chloroform are preferable from the viewpoint of solubility of components in the matrix resin composition and applicability to the resin fiber sheet. These organic solvents may be used alone or in combination of two or more thereof. It is preferable that aromatic compounds (i.e., compounds having an aromatic ring) such as toluene and xylene be substantially not included. In an aspect, the organic solvent is substantially free of aromatic compounds. Specifically, the term “organic solvent substantially free of aromatic compounds” means that the content of aromatic compounds in the organic solvent is less than 1% by mass, and may be 0.5% by mass or less, 0.2% by mass or less. 0.1% by mass or less, or 0% by mass. When the content of the aromatic compound is less than 1% by mass, the tensile strength of the prepreg after application can be suitably maintained. Further, in an aspect, the organic solvent is substantially free of toluene. Specifically, “the organic solvent is substantially free of toluene” means that the toluene content in the organic solvent is less than 1% by mass, and may be 0.5% by mass or less, 0.2% by mass or less, 0.1% by mass or less, or 0% by mass.

### <Prepreg Applications>

The prepreg of the present embodiment can be used, for example, for forming an insulating layer of a printed wiring board or for forming a buildup layer of a printed wiring board (i.e., a wiring layer of the board when the printed wiring board is a buildup board).

### <Support-Attached Prepreg>

The present embodiment also provides a support-attached prepreg comprising a support and the prepreg of the present embodiment supported on the support. The support-attached prepreg may have a support on one or both sides of the prepreg. Examples of the support-attached prepreg include metal foil with resin, an interlayer insulation material, and the like. The support may be a resin film, metal foil, or the like. As the (a) low molecular weight PPE, (b) cross-linking agent, (c) silica filler, (d) organic peroxide, (e) thermoplastic resin, (f) flame retardant, and (g) organic solvent, those described above can be used.

Examples of the resin film include films of one or more polymers selected from polyesters such as polyethylene terephthalate (PET) and polyethylene naphthalate (PEN); acrylic polymers such as polycarbonate (PC) and polymethyl methacrylate (PMMA); cyclic polyolefin; cellulose polymers such as triacetyl cellulose (TAC); polyether sulfide (PES), polyether ketones; and polyimides. Among these, polyethylene terephthalate and polyethylene naphthalate are preferable, and polyethylene terephthalate is particularly preferable because of the low cost thereof.

Examples of the metal foil include copper foil, aluminum foil, etc., and copper foil is preferable. As the copper foil, a foil composed only of copper may be used, or a foil composed of an alloy of copper and another metal (for example, one or more selected from tin, chromium, silver, magnesium, nickel, zirconium, silicon, and titanium) may be used.

The surface of the support to be bonded to the prepreg may be subjected to surface treatment such as matte treatment or corona treatment.

### <Support-Attached Prepreg Production Method>

The support-attached prepreg production method of the present embodiment may comprise:
a step of continuously delivering a support;
a first application step of continuously applying a matrix resin composition varnish on the support;
a step of delivering the resin fiber sheet of the present embodiment by applying tension thereto with a non-mirrored roller in contact thereto,
a step of contacting the matrix resin composition varnish applied on the support with the surface of the resin fiber sheet to obtain a first resin fiber sheet composite; and
a first drying step of drying the first resin fiber sheet composite.

The above method may further comprise:
a second application step of continuously applying the matrix resin composition varnish on the first resin fiber sheet composite dried in the first drying step to obtain a second resin fiber sheet composite; and
a second drying step of drying the second resin fiber sheet composite.

### <Application Step>

In the application step, the matrix resin varnish is continuously applied on the delivered support. Though the method of applying the matrix resin composition varnish on the support is not particularly limited, examples thereof include various methods such as a slot die, gravure coater, bar coater, roll coater, doctor coater, PDN coater, blade coater, and impregnation coater. These methods can be selected as appropriate, taking into consideration the thickness of the application liquid layer to be produced, the physical properties of the material such as the application liquid, and the application conditions.

### <Step of Delivering Resin Fiber Sheet>

In this step, in parallel with the application step, the resin fiber sheet may be delivered by applying tension thereto with a non-mirrored roller in contact thereto. The roller for delivering the resin fiber sheet may include a unit which detects the tension of the resin fiber sheet and a unit which controls the tension, and the tension may be controlled by these units.

### [Non-Mirrored Roller]

When continuously producing support-attached prepregs, it is preferable to deliver the resin fiber sheet with a non-mirrored roller in contact thereto. Since non-mirrored rollers can diffusely reflect reflected light when irradiated with light, have suitable sliding properties with resin fiber sheets, and can easily control tension, wrinkling can be suppressed. As the non-mirrored roller, a satin-finished roller that has been subjected to a blast treatment and has a finely textured roller surface is suitable. As the non-mirrored roller, a mirrored roller laminated with a highly slippery resin tape, such as a polytetrafluoroethylene (PTFE) or silicone resin tape, is also suitable. The degree of fine texturing on the roller surface is preferably, as an arithmetic mean roughness (Ra), in the range of 0.5 to 10.0 μm, more preferably in the range of 0.6 to 5.0 μm, and further preferably in the range of 0.7 to 3.0 μm.

When Ra is 0.5 μm or more, the sliding properties between the roller and the resin fiber sheet are suitable, and tension can be easily controlled. When Ra is 10.0 μm or less, local friction such as fibers of the resin fiber sheet being caught in convex portions of the fine texturing is less likely to occur, and damage such as unraveling of the fibers of the resin fiber sheet is reduced.

The arithmetic mean roughness (Ra) of the fine texturing on the roller surface can be measured using an optical microscope with a confocal optical system. For example, an OPTELICS S130 device manufactured by Lasertec Corporation is suitable. The Ra of the non-mirrored roller is measured under the following conditions. After acquiring texturing data of the roller surface with an objective lens magnification of 20-fold and a wavelength selection of 546 nm, the processing range (line ROI button) is selected for the Z Image data so that the processing range is approximately 100 μm in the direction parallel to the width direction of the roller (i.e., the direction in which the rotation axis extends), and the arithmetic mean roughness (Ra) is calculated in the LM measurement mode. The Ra value is measured at five arbitrary positions where the resin fiber sheet contacts, and the average value is used.

As another aspect of the support-attached prepreg production method, a production method comprising the steps of: laminating the resin fiber sheet on the surface of a matrix resin layer, which is formed on the support and which is solid at room temperature; and thereafter heating and pressing the resin fiber sheet in a state where the surface of the resin fiber sheet on the side opposite the matrix resin layer is laminated on one or both sides of the base material is preferable.

Examples of the base material include the prepreg of the present disclosure or a flexible film. In an aspect, the flexible film may be the same material as the support of the present disclosure.

Heating is preferably carried out to a temperature equal to or higher than the glass transition temperature (Tg) of the matrix resin, which is solid at room temperature, and the pressure can be adjusted as appropriate depending on the type of resin and the heating conditions.

### <Laminate (Laminated Body)>

The present embodiment also provides a laminate (laminated body) obtained using the prepreg or support-attached prepreg of the present embodiment. For example, a metal-clad laminate is obtained by laminating the prepreg of the present embodiment with a metal foil followed by curing. The metal-clad laminate preferably has a form in which a cured product of the prepreg (also referred to as a “cured composite”) and a metal foil are laminated and adhered to each other, and is suitably used as a material for electronic circuit boards. Examples of the metal foil include aluminum foil and copper foil, and among these, copper foil is preferable because it has low electrical resistance. The cured composite to be combined with the metal foil may be one or more sheets, and depending on the purpose, the composite is processed into a laminate by laminating the metal foil on one or both sides thereof. Examples of the method for the production of the laminate include a method in which the prepreg described above is formed, overlaying it with a metal foil, and then curing the matrix resin composition to produce a laminate in which the cured laminated body and metal foil are laminated. Furthermore, examples of another method for the production of the laminated body include a method in which after the prepreg described above is formed, a resin fiber sheet is laminated thereon, and in a state where the prepreg is laminated thereon, heating and pressure are applied under vacuum conditions to obtain a laminate.

### <Printed Wiring Board>

The printed wiring board according to the present embodiment may be obtained by removing a portion of the metal foil from a metal-clad laminate. Further, the printed wiring board may comprise an insulating layer formed of a cured product of the prepreg according to the present embodiment, or a build-up insulating layer formed of a cured product of the prepreg according to the present embodiment.

The printed wiring board of the present embodiment can typically be formed using the prepreg of the present embodiment described above by a method of pressurizing and heat-molding. The base material may be the same as the resin fiber sheet described above regarding the prepreg. Since the printed wiring board of the present embodiment is produced from the prepreg of the present embodiment, it has excellent heat resistance and electrical properties (low dielectric constant and low dielectric loss tangent), whereby fluctuations in electrical properties due to environmental changes can be suppressed, and has excellent insulation reliability and mechanical properties.

### <Semiconductor Device>

The present embodiment also provides a semiconductor device comprising the printed wiring board of the present embodiment. Specifically, the semiconductor device can be produced using the printed wiring board according to the present embodiment.

Examples of semiconductor devices include various semiconductor devices used in electrical products (for example, computers, mobile phones, digital cameras, and televisions), and vehicles (for example, motorcycles, automobiles, trains, ships, and aircraft).

The semiconductor device according to the present embodiment can be produced by mounting a semiconductor chip as a component on a conductive portion of a printed wiring board, and specifically, a portion of the printed wiring board which transmits electric signals. The conductive portion may be arranged, for example, on the surface of the semiconductor device or embedded within the semiconductor device, and the arrangement thereof is not limited. Furthermore, the semiconductor chip includes all electric circuit elements formed using semiconductor materials.

The method for mounting the semiconductor chip when producing the semiconductor device according to the present embodiment is not particularly limited, and examples thereof include a wire bonding mounting method, a flip chip mounting method, a mounting method using a BBUL (Bumpless Build-Up Layer), a mounting method using anisotropic conductive film (ACF), and a mounting method using non-conductive film (NCF). Note that BBUL is a mounting method in which a semiconductor chip is directly embedded in a recessed portion of a printed wiring board without providing bumps to connect the semiconductor chip with wiring on the printed wiring board.

### EXAMPLES

The present embodiment will be described in detail by way of the following Examples. However, the present embodiment is not limited to these Examples.

### <Preparation of PPE Composition for Resin Fiber Sheet>

A PPE composition was obtained by melt-kneading PPE, sPS, LCP, or atactic PS (polystyrene) having the number average molecular weight (Mn) shown in Table 1 at 320° C. in a twin-screw extruder at the blending ratio (mass-based) shown in Table 1. The materials used are as follows.
PPE (product name “S202A”, manufactured by Asahi Kasei Corporation, Mn: 15,000)
PPE (product name “S203A”, manufactured by Asahi Kasei Corporation, Mn: 11,000)
sPS (product name “60ZC”, manufactured by Idemitsu Kosan Co., Ltd., Mw: 250,000)
sPS (product name “90ZC”, manufactured by Idemitsu Kosan Co., Ltd., Mw: 200,000)
LCP (product name “A-8100”, manufactured by Ueno Fine Chemicals Industry, Ltd., melting point 220° C.)
Atactic PS (product name “GPPS680”, manufactured by PS Japan Corporation, Mw: 200,000)

### <Preparation of Resin Fibers>

The compositions shown in Table 1 were each extruded and spun through a spinneret using a melt spinning machine to produce a multi-filament. The spinning temperature was adjusted to a spinneret surface temperature of 293° C. The hole diameter of the spinneret was 0.23 mm, and the number of holes was 24. Since the appropriate spinning speed differs depending on the resin composition, the spinning speed was changed. After spinning, the multi-filament was stretched at a preheating temperature of 100° C. and a stretching ratio to achieve an elongation of 20%, and after heat-setting at 155° C., a fiber of 46 dtex and 24 filaments was wound at a relaxation ratio of 0.980. Two thereof were combined to ultimately obtain a fiber of 92 dtex and 48 filaments.

### <Production of Cloth as Resin Fiber Sheet>

After weaving, physical processing, de-sizing, surface treatment, and fiber-opening processing of the multi-filaments described above, cloths having warp and weft weave densities of 30 fibers/inch, a thickness of 100 μm, and an opening ratio as shown in Table 1 were produced.

### <Preparation of Matrix Resin Composition Varnish>

### [Materials]

The following materials were used.

### (Low Molecular Weight PPE)

Terminal methacrylic group-modified PPE (product name “SA9000”, manufactured by Sabic

### Innovative Plastics, Mn: 2756)

### (Cross-Linking Agent)

RICON100 (manufactured by CRAY VALLEY, molecular weight: 4500)
TAIC (manufactured by Mitsubishi Chemical Corporation, molecular weight: 249.7)

### (Organic Peroxide)

Bis(1-tert-butylperoxy-1-methylethyl)benzene (product name “Perbutyl P”, manufactured by NOF Corporation)

### (Flame Retardant)

Decabromodiphenylethane (product name “SAYTEX8010”, manufactured by Albemarle)

### (Silica Filler)

Spherical silica, average particle diameter 1.1 μm (SO-C4 manufactured by Admatex)

Each material was weighed in advance, methyl ethyl ketone (as an organic solvent) was introduced into a container, and while stirring with a mixer, the following materials were added at the mass ratio shown below, and mixed for 5 hours or longer to prepare a matrix resin composition varnish having a solid content of 50% by mass.
Varnish 1: Low molecular weight PPE/RICON100/TAIC/organic peroxide/flame retardant/silica filler=55/10/10/1/14/10
Varnish 2: Low molecular weight PPE/TAIC/organic peroxide/flame retardant/silica filler=55/20/1/14/10

### Prepreg Preparation

### Examples 1 to 7, Comparative Examples 1 and 2

Prepregs were prepared by impregnating the cloths with a resin composition varnish at a constant tension of approximately 100 N/m, scraping with a slit, and drying at 120° C. for 3 minutes.

### Reference Example 1

A prepreg was prepared in the same manner as in Example 1, except that a low dielectric constant glass cloth L2116 (weave densities: 60×58 fibers/inch, thickness: 95 μm, opening ratio: 5%) was used.

### <Evaluation Methods>

### (1) Number Average Molecular Weight

Using gel permeation chromatography (GPC), the number average molecular weight and weight average molecular weight were determined by comparison with the elution time of standard polystyrene of a known molecular weight. Specifically, after preparing a measurement sample having a sample concentration of 0.2 w/vol % (solvent: chloroform), using an HLC-8220GPC (manufactured by Tosoh Corporation) as the measurement device, measurement was performed under the conditions of column: Shodex GPC KF-405L HQ×3 (manufactured by Showa Denko K.K.), eluent: chloroform, injection volume: 20 μL, flow rate: 0.3 mL/min, column temperature: 40° C., and detector: RI.

(2) Single filament Diameter

Cross-sections of 100 arbitrary filaments were imaged using a scanning electron microscope (SEMEDX3TypeN, Hitachi Science Systems Co., Ltd.), the diameters thereof were measured, and the average value was calculated.

### (3) Warp and Weft Weave Densities of Cloth

Measurements were made in both the warp and weft directions in accordance with JIS R3420.

### (4) Cloth Opening Ratio

A center part of a cloth roll was cut from a 100 mm width (approximately 4-inch width) on all sides, in a cloth surface morphology image by optical microscope, the total warp width (i.e., the total warp width in the entire 100 mm×100 mm cloth) and the total weft width (i.e., the weft total width in the entire 100 mm×100 mm cloth) were measured, and the average value of each of the warp and weft yarns was calculated. Based on these average values and the weave densities determined as described above, the opening ratio was calculated according to the following formula:

$$Opening ratio = ( 25.4 mm / warp density - warp yarn width mm ) \times ( 25.4 mm / weft density - weft yarn width mm ) / ( ( 25.4 mm / warp density ) \times ( 25.4 mm / weft density ) )$$

### (5) Cloth Thickness

Measured in accordance with JIS R3420.

### (6) Weavability

The yarn breakage stop during weaving was relatively evaluated among the Examples and Comparative Examples, and was rated as good: A, slightly poor: B, and poor: C.

### (7) Dielectric Constant and Dielectric Loss Tangent (Electrical Properties, 10 GHz)

A laminate was produced by overlaying six prepregs, performing vacuum pressing at a pressure of 5 kg/cm² while heating from room temperature at a temperature increase rate of 3° C./min, when the temperature reached 130° C., performing vacuum pressing at a pressure of 40 kg/cm² while heating at a temperature increase rate of 3° C./min, and when the temperature reached 200° C., performing vacuum pressing at a pressure of 40 kg/cm² for 60 minutes while maintaining the temperature at 200° C. Regarding this laminate, the dielectric constant and dielectric loss tangent at 10 GHz were measured using the cavity resonance method. Measurement was performed using a network analyzer (N5230A, manufactured by Agilent Technologies) and a cavity resonator (Cavity Resonator CP series) manufactured by Kanto Electronics Application and Development, Inc. as measurement devices.

### (8) Substrate Warpage Amount

A laminate was produced in the same manner as in (7) above by overlaying two prepregs, four arbitrary 50 mm square samples were cut out, and the warpage amount at each of the four corners of each sample (larger on the front and back) was measured using calipers. The average value of the four corners was calculated and used as the substrate warpage amount.

The results are shown in Table 1.

### (9) Toughness

A fiber sample was measured in accordance with JIS L1013 (2010) tensile strength and elongation, and a tensile strength-elongation curve was drawn. The test conditions were a constant speed extension testing machine, a grip interval of 20 cm, and a tensile speed of 20 cm/min. Furthermore, when the tensile strength at the time of cutting was less than the maximum strength, the maximum tensile strength and elongation at that time were measured. The toughness, which is the product of the strength (A) and the square root of the elongation (B), was calculated.

$$\begin{matrix}Strength ( A ) = tensile strength at cutting ( cN ) / fineness ( dtex ) \\ Elongation ( B ) = elongation at cutting ( \% ) \\ Toughness = ( A ) \times {\{ ( B ) \}}^{1 / 2}\end{matrix}$$

### (10) Thermal Stress Rise Temperature

Measurement was performed using a KE-2S thermal stress measuring instrument manufactured by Intec Corporation (formerly manufactured by Kanebo Engineering Corporation) at a heating rate of 150° C./min. The sample was formed into two 0.1 m loops, and the initial tension was set to fineness (dtex)×0.03 cN. Note that the thermal stress rise temperature is the temperature at the inflection point where stress increases.

### (11) Overall Evaluation

Samples which satisfied all of a toughness of 5 to 30, a thermal stress rise temperature of 100 to 190° C., a weavability of A, a cloth dielectric constant of 3.0 or less, a cloth dielectric loss tangent of 0.001 or less, and a substrate warpage of 5 mm or less were evaluated as excellent, those having a weavability of B but satisfying all of the other conditions above were evaluated as good, and all others were evaluated as poor.

As shown in Table 1, though the overall evaluation was excellent or good under the conditions shown in the Examples, the overall evaluation was poor under the conditions shown in the Comparative Examples.

TABLE 1

| | | Ex 1 | Ex 2 | Ex 3 | Ex 4 | Ex 5 | Ex 6 |
|---|---|---|---|---|---|---|---|
| Structure of PPE | PPE - Mn: 11,000 | | 10 | 35 | 25 | | |
| composition for | PPE - Mn: 15,000 | 25 | | | | 20 | 25 |
| resin fiber sheet | sPS - Mw: 200,000 | | 90 | 65 | 75 | | |
| | sPS - Mw: 250,000 | 75 | | | | 75 | 75 |
| | LCP - melting point: 220° C. | | | | | 5 | |
| | Atactic PS - Mw: 200,000 | | | | | | |
| | L2116 | | | | | | |
| Composition | PPE/TAIC/RICON/flame | 100 | 100 | 100 | 100 | 100 | |
| (parts by mass) | retardant/silica/peroxide = | | | | | | |
| | 55/10/10/14/10/1 mixture | | | | | | |
| | PPE/TAIC/flame | | | | | | 100 |
| | retardant/silica/peroxide = | | | | | | |
| | 55/20/14/4/10/1 mixture | | | | | | |
| Fiber evaluation | Spinning speed (m/min) | 3000 | 2000 | 3500 | 2500 | 300 | 3000 |
| | Fiber toughness | 7.4 | 7 | 7.3 | 8 | 5.2 | 7.4 |
| | Fiber diameter (μm) | 16 | 16 | 16 | 16 | 16 | 16 |
| | Thermal stress rise | 135 | 115 | 140 | 135 | 140 | 130 |
| | temperature (° C.) | | | | | | |
| Cloth evaluation | Weavability | A | A | A | A | B | A |
| | Opening ratio (%) | 20 | 20 | 20 | 20 | 20 | 20 |
| | Dielectric constant | 2.5 | 2.5 | 2.5 | 2.5 | 2.5 | 2.5 |
| | Dielectric loss tangent | 0.0006 | 0.0003 | 0.0008 | 0.0006 | 0.0008 | 0.0006 |
| Substrate | Dielectric constant | 2.6 | 2.6 | 2.6 | 2.6 | 2.6 | 2.6 |
| evaluation | Dielectric loss tangent | 0.0015 | 0.0012 | 0.0018 | 0.0015 | 0.002 | 0.0015 |
| | Warpage amount (mm) | 2 | 2 | 1 | 2 | 2 | 5 |

| | | | | | | |
|---|---|---|---|---|---|---|
| Overall Evaluation | Excellent | Excellent | Excellent | Excellent | Good | Excellent |

| | | Ex 7 | Comp Ex 1 | Comp Ex 2 | Ref Ex 1 |
|---|---|---|---|---|---|
| Structure of PPE | PPE - Mn: 11,000 | | 0 | | |
| composition for | PPE - Mn: 15,000 | 50 | | 50 | |
| resin fiber sheet | sPS - Mw: 200,000 | | 100 | | |
| | sPS - Mw: 250,000 | 50 | | | |
| | LCP - melting point: 220° C. | | | | |
| | Atactic PS - Mw: 200,000 | | | 50 | |
| | L2116 | | | | 100 |
| Composition | PPE/TAIC/RICON/flame | 100 | 100 | 100 | 100 |
| (parts by mass) | retardant/silica/peroxide = | | | | |
| | 55/10/10/14/10/1 mixture | | | | |
| | PPE/TAIC/flame | | | | |
| | retardant/silica/peroxide = | | | | |
| | 55/20/14/4/10/1 mixture | | | | |
| Fiber evaluation | Spinning speed (m/min) | 1000 | 800 | 300 | — |
| | Fiber toughness | 4.6 | 7 | 1.9 | 15 |
| | Fiber diameter (μm) | 16 | 16 | 30 | — |
| | Thermal stress rise | 150 | 90 | 140 | — |
| | temperature (° C.) | | | | |
| Cloth evaluation | Weavability | B | B | C | A |
| | Opening ratio (%) | 20 | 20 | 20 | 35 |
| | Dielectric constant | 2.6 | 2.5 | 2.8 | 4.3 |
| | Dielectric loss tangent | 0.001 | 0.0002 | 0.0018 | 0.0023 |
| Substrate | Dielectric constant | 2.7 | 2.6 | 2.6 | 3.3 |
| evaluation | Dielectric loss tangent | 0.0021 | 0.0013 | 0.0028 | 0.004 |
| | Warpage amount (mm) | 1 | 15 | 30 | 5 |

| | | | | |
|---|---|---|---|---|
| Overall Evaluation | Good | Poor | Poor | Poor |

1. A resin fiber sheet, composed of polyphenylene ether composition fibers, wherein
the polyphenylene ether composition fibers contain greater than 0% by mass and 95% by mass or less of polyphenylene ether, and a total of 5% by mass or more and less than 100% by mass of liquid crystal polyester, syndiotactic polystyrene, or both, and have a single-filament diameter of 1 to 50 μm.

2. (canceled)

3. The resin fiber sheet according to claim 1, wherein a toughness of the polyphenylene ether composition fibers is 5 or more and 30 or less.

4. The resin fiber sheet according to claim 1, wherein a thermal stress rise temperature of the polyphenylene ether composition fibers is 100° C. or higher and 190° C. or lower.

5. (canceled)

6. The resin fiber sheet according to claim 1, wherein a number average molecular weight of the polyphenylene ether is 9000 to 21000.

7. The resin fiber sheet according to claim 1, wherein the resin fiber sheet is a resin fiber cloth with warp and weft weave densities of 20 to 200 fibers/inch and an opening ratio of 1 to 30%.

8. (canceled)

9. The resin fiber sheet according to claim 1, wherein the resin fiber sheet is a non-woven fabric, and
the polyphenylene ether composition fibers are composed of single filaments having a single-filament diameter of 1 to 50 μm.

10. A prepreg comprising the resin fiber sheet according to claim 1 and a matrix resin composition.

11. The prepreg according to claim 10, wherein the matrix resin composition contains at least one thermosetting resin selected from the group consisting of an epoxy resin, cyanate ester resin, bismaleimide resin, polyphenylene ether resin, and bismaleimide triazine resin.

12. The prepreg according to claim 11, wherein the polyphenylene ether resin contains a low molecular weight polyphenylene ether having a number average molecular weight of 1000 to 5000.

13. The prepreg according to claim 10, wherein the matrix resin composition further contains a silica filler.

14. The prepreg according to claim 13, wherein the silica filler is spherical silica having an average particle diameter of 2 μm or less.

15. The prepreg according to claim 13, wherein a content of the silica filler in the matrix resin composition is 10 to 50% by mass.

16. The prepreg according to claim 10, wherein the matrix resin composition further contains a cross-linking agent.

17. The prepreg according to claim 16, wherein the cross-linking agent is a styrene-butadiene copolymer having a number average molecular weight of 1000 to 7000 and containing 20% by mass or more of styrene-derived structural units.

18. The prepreg according to claim 16, wherein a content of the cross-linking agent in the matrix resin composition is 3 to 30% by mass.

19-27. (canceled)

28. A support-attached prepreg, comprising the prepreg according to claim 10 and a support arranged on one or both sides of the prepreg.

29. The support-attached prepreg according to claim 28, wherein the support is a resin film or a metal foil.

30.-34. (canceled)

35. A semiconductor device, comprising the resin fiber sheet according to claim 1.

36. (canceled)
